(19) United States
(12) Patent Application Publication
(10) Pub. No.: US 2015/0078077 A1
(43) Pub. Date: Mar. 19, 2015

(54) NONVOLATILE SEMICONDUCTOR MEMORY DEVICE

(71) Applicant: KABUSHIKI KAISHA TOSHIBA, Tokyo (JP)

(72) Inventor: Kazushige KANDA, Kanagawa (JP)

(73) Assignee: KABUSHIKI KAISHA TOSHIBA, Tokyo (JP)

(21) Appl. No.: 14/192,428

(22) Filed: Feb. 27, 2014

(30) Foreign Application Priority Data
Sep. 17, 2013 (JP) 2013-191383

(51) Int. Cl. G11C 16/24; G11C 16/26; G11C 16/04

(52) U.S. Cl. CPC G11C 16/24; G11C 16/0483; G11C 16/26
USPC 365/185.2; 365/185.18; 365/185.25

(57) ABSTRACT

A nonvolatile semiconductor memory device includes a memory string that includes a plurality of first memory cells, a plurality of second memory cells, and a transistor electrically connected between the plurality of first memory cells and the plurality of second memory cells, and a control circuit that performs a program operation by applying a program voltage to a gate of a selected first memory cell among the plurality of first memory cells and a gate of a selected second memory cell among the plurality of second memory cells, a pass voltage lower than the program voltage to other memory cells in the plurality of first and second memory cells, and a control voltage to a gate of the transistor.

### CROSS-REFERENCE TO RELATED APPLICATION

This application is based upon and claims the benefit of priority from Japanese Patent Application No. 2013-191383, filed Sep. 17, 2013, the entire contents of which are incorporated herein by reference.

### FIELD

Embodiments described herein relate generally to a nonvolatile semiconductor memory device.

### BACKGROUND

Semiconductor memories are used everywhere from large-sized computers to personal computers, household electrical appliances, mobile phones, and the like. Flash memory is one type of semiconductor memory that has attracted much attention. The flash memory is used in various information apparatuses such as mobile phones or digital cameras because the memory is nonvolatile and a structure thereof is appropriate for high integration.

### DESCRIPTION OF THE DRAWINGS

FIG. 1 is an overall configuration diagram of a nonvolatile semiconductor memory device according to a first embodiment.

FIG. 2 is a perspective view illustrating a structure of a cell array of the nonvolatile semiconductor memory device according to the first embodiment.

FIG. 3 is a circuit diagram of a memory string of the cell array in the nonvolatile semiconductor memory device according to the first embodiment.

FIG. 4 is a diagram illustrating an example of a configuration of a sense amplifier unit of the nonvolatile semiconductor memory device according to the first embodiment.

FIG. 5 is a diagram illustrating an example of a configuration of the sense amplifier unit of the nonvolatile semiconductor memory device according to the first embodiment.

FIG. 6 is a cross-sectional view of the cell array of the nonvolatile semiconductor memory device according to the first embodiment.

FIG. 7 is a cross-sectional view of the cell array of the nonvolatile semiconductor memory device according to the first embodiment.

FIG. 8 is a diagram illustrating a relationship between a threshold distribution and data in a memory transistor of the nonvolatile semiconductor memory device according to the first embodiment.

FIG. 9 is a timing chart during a writing operation in the nonvolatile semiconductor memory device according to the first embodiment.

FIG. 10 is a timing chart during the reading operation in the nonvolatile semiconductor memory device according to the first embodiment.

FIG. 11 is a timing chart during the reading operation in the nonvolatile semiconductor memory device according to the first embodiment.

FIG. 12 is a circuit diagram of a memory string of a cell array in a nonvolatile semiconductor memory device according to a second embodiment.

FIG. 13 is a timing chart during a writing operation in the nonvolatile semiconductor memory device according to the second embodiment.

FIG. 14 is a perspective view illustrating a structure of a cell array of a nonvolatile semiconductor memory device according to a third embodiment.

FIG. 15 is a plan view of the cell array of the nonvolatile semiconductor memory device according to the third embodiment.

FIG. 16 is a plan view of the cell array of the nonvolatile semiconductor memory device according to the third embodiment.

FIG. 17 is a perspective view illustrating a structure of the cell array of the nonvolatile semiconductor memory device according to the third embodiment.

FIG. 18 is a circuit diagram of a memory string of a cell array in a nonvolatile semiconductor memory device according to a comparative example of the first embodiment.

FIG. 19 is a timing chart during a writing operation in the nonvolatile semiconductor memory device according to the comparative example.

### DETAILED DESCRIPTION

The present exemplary embodiments provide a nonvolatile semiconductor memory device capable of improving reliability and performance of a writing operation.

In general, according to one embodiment, a nonvolatile semiconductor memory device includes a memory string that includes a plurality of first memory cells, a plurality of second memory cells, and a transistor electrically connected between the plurality of first memory cells and the plurality of second memory cells, and a control circuit configured to perform a program operation by applying a program voltage to a gate of a selected first memory cell among the plurality of first memory cells and a gate of a selected second memory cell among the plurality of second memory cells, a pass voltage lower than the program voltage to other memory cells in the plurality of first and second memory cells, and a first control voltage lower than the pass voltage to a gate of the transistor.

Hereinafter, with reference to the drawings, a semiconductor memory device according to exemplary embodiments will be described.

### First Embodiment

### Overall Configuration

First, an overall configuration of a nonvolatile semiconductor memory device according to the first embodiment will be described.

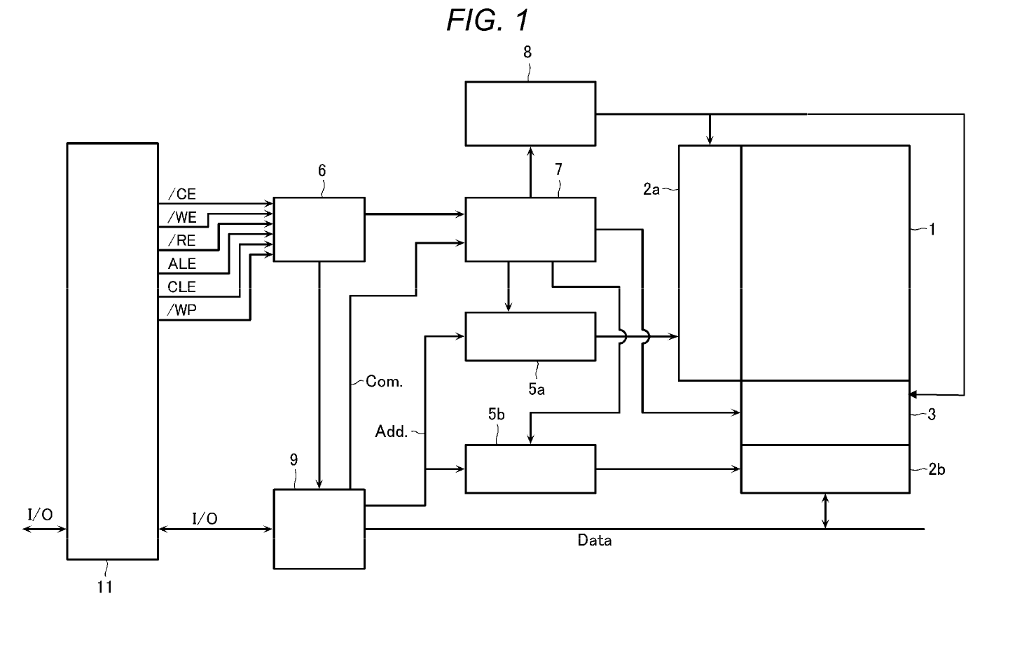

FIG. 1 is an overall configuration diagram of the nonvolatile semiconductor memory device according to the present embodiment.

A NAND flash memory, which is the nonvolatile semiconductor memory device according to the present embodiment, is provided with a cell array 1 and peripheral circuits including a control circuit. The control circuit includes a row decoder/word line driver 2a, a column decoder 2b, a page buffer 3, a row address register 5a, a column address register 5b, a logic control circuit 6, a sequence control circuit 7, a high voltage generation circuit 8, an I/O buffer 9, and a controller 11.

The cell array 1 has a so-called bit-cost-scalable (BiCS) structure. The cell array 1 has a plurality of memory strings in the same manner as a cell array of a NAND flash memory with a planar structure. Each of the memory strings has a plurality of cells connected in series. Each of the cells is formed by a transistor (hereinafter, referred to as a “cell transistor”) having a charge storage layer. The cell array 1 will be described in detail later.

The row decoder/word line driver 2a drives word lines and selection gate lines of the cell array 1. The page buffer 3 has sense amplifier units and data holding circuits for one page of data, and controls reading and writing of data of the cell array 1 in units of a page of 8 Kbytes or 16 Kbytes. Read data of one page of the page buffer 3 is sequentially column-selected, for example, every 8 bits or 16 bits, by the column decoder 2b, and is output to an external I/O terminal via the I/O buffer 9. Data to be written which is supplied from the I/O buffer 9 is selected for each page by the column decoder 2b so as to be loaded to the page buffer 3. A row address signal and a column address signal are input via the I/O buffer 9, and are respectively transmitted to the row decoder/word line driver 2a and the column decoder 2b. The row address register 5a holds an erasure block address during an erasure operation, and holds a page address during a writing operation or a reading operation. A leading column address required to load data to be written before starting a writing operation or a leading column address required in a reading operation is input to the column address register 5b. If a writing enable signal /WE or a reading enable signal /RE is toggled in a predetermined condition, the column address register 5b increments input column address. The logic control circuit 6 controls inputting of a command or an address, and inputting and outputting of data on the basis of control signals such as a chip enable signal /CE, a command latch enable signal CLE, an address latch enable signal ALE, the writing enable signal /WE, and the reading enable signal /RE. The sequence control circuit 7 receives a command from the logic control circuit 6 so as to control an erasure operation, a reading operation, or a writing operation. In other words, the sequence control circuit 7 controls the row address register 5a, the column address register 5b, the row decoder/word line driver 2a, and the like, so as to control an erasure operation, a reading operation, or a writing operation. The high voltage generation circuit 8 is controlled by the sequence control circuit 7 so as to generate predetermined voltages required in various operations. The controller 11 controls a writing operation or the like in a condition which is suitable for a current reading state or the like. In addition, the page buffer 3 may include a data latch DL which holds open failure information, which is described later.

### Cell Array

Next, a specific example of the cell array 1 will be described.

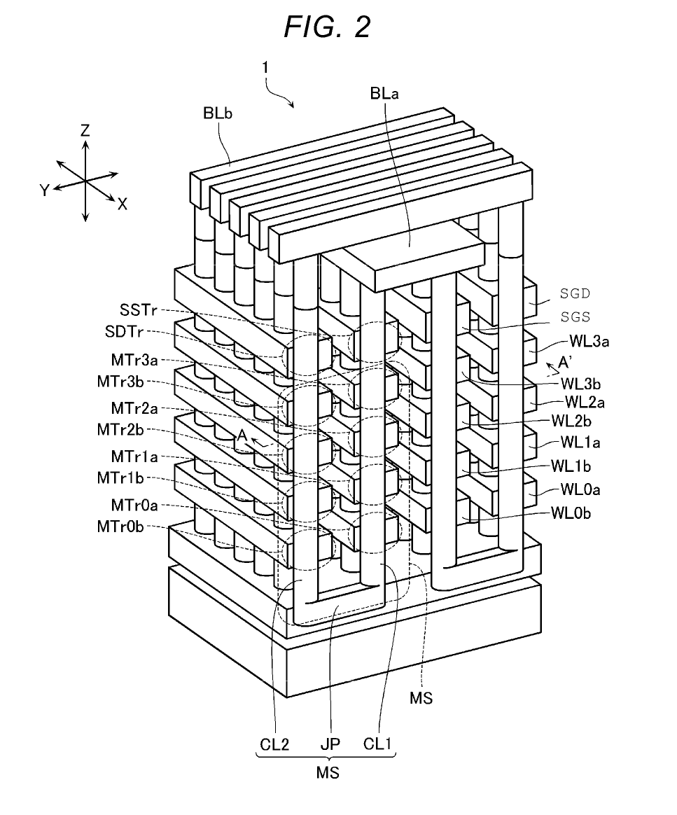

FIG. 2 is a perspective view illustrating a structure of the cell array of the nonvolatile semiconductor memory device according to the present embodiment. FIG. 2 illustrates three directions, an X direction, a Y direction, and a Z direction intersecting each other.

The cell array 1 includes, on a semiconductor substrate, a plurality of word lines WL which are arranged in the Y direction and Z direction in a two-dimensional manner and extend in the X direction, a plurality of selection gate lines which are arranged in the Y direction and extend in the X direction, a plurality of bit lines BLa which are arranged in the Y direction and extend in the X direction, and a plurality of bit lines BLb which are arranged in the X direction and extend in the Y direction. In addition, the plurality of selection gate lines include a source side selection gate line SGS and a drain side selection gate line SGD which are alternately arranged in twos in the Y direction. Further, only one bit line BLa is illustrated in FIG. 2. Furthermore, a plurality of pillars which are arranged in a two-dimensional arrangement in the X direction and Y direction are provided. Each pillar, in FIG. 2, has a pillar-shaped part CL1 of which an upper end is electrically connected to the bit line BLa via a source side selection transistor SSTr controlled by the source side selection gate line SGS and which extends in the Z direction to penetrate through the plurality of word lines WL, a connection part JP of which a right end is connected to a lower end of the pillar-shaped part CL1 and which extends through an interlayer insulating film on the semiconductor substrate in the Y direction, and a pillar-shaped part CL2 of which a lower end is connected to a left end of the connection part JP, an upper end is electrically connected to the bit line BLb via a drain side selection transistor SDTr controlled by the drain side selection gate line SGD and which extends in the Z direction to penetrate through the plurality of word lines WL. Here, a plurality of memory strings MS sharing the word line WL become a memory block MB. In addition, the bit lines BLa and BLb are collectively indicated by a “bit line BL” without the suffixes a and b in some cases. Similarly, it is noted that other constituent elements such as the word line WL are also indicated without the suffixes if collectively indicated.

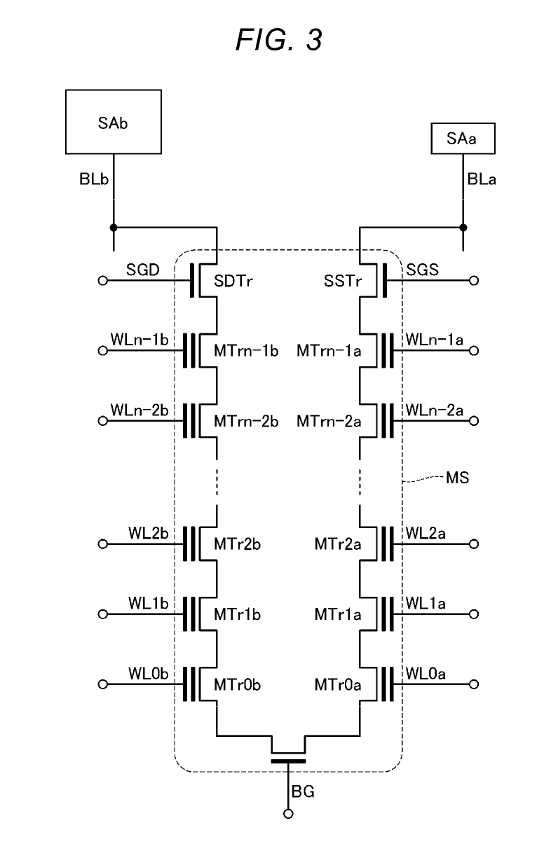

FIG. 3 is a circuit diagram of the memory string of the cell array in the nonvolatile semiconductor memory device according to the present embodiment.

FIG. 3 illustrates, from the bit line BLa to the bit line BLb, the source side selection transistor SSTr which has the source side selection gate line SGS as a gate, the memory string MS, and the drain side selection transistor SDTr which has the drain side selection gate line SGD as a gate, connected in series to each other. The memory string MS includes n (where n is a positive integer) memory transistors MTrn-1a to MTr0a connected in series to each other, a back gate transistor BGTr (a switch unit) having a back gate line BG as a gate, and n memory transistors MTr0b to MTrn-1b connected in series to each other. Each memory transistor MTr is a transistor having a charge storage layer which can electrically rewrite a threshold voltage Vth, and has a gate connected to the word line WL. In addition, the memory transistors MTr0a to MTrn-1a belong to the pillar-shaped part CL1, the back gate transistor BGTr belongs to the connection part JP, and the memory transistors MTr0b to MTrn-1b belong to the pillar-shaped part CL2.

In addition, the bit line BLa is electrically connected to a sense amplifier unit SAa (a first sense amplifier unit). The sense amplifier unit SAa has a precharge circuit for the bit line BLa. The bit line BLb is electrically connected to a sense amplifier unit SAb (a second sense amplifier unit). The sense amplifier unit SAb has a precharge circuit for the bit line BLb and a current sense circuit of the bit line BLb. The sense amplifier units SAa and SAb are included in, for example, the page buffer 3 of the control circuit.

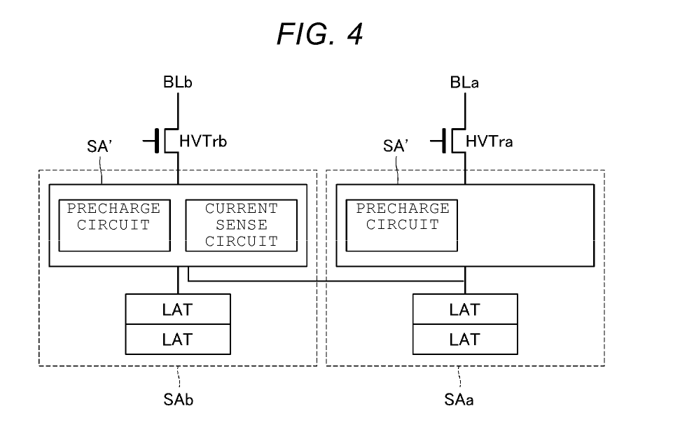

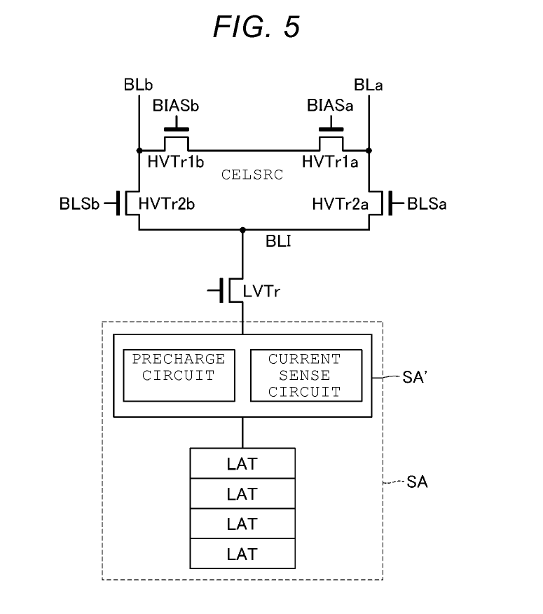

FIGS. 4 and 5 are diagrams illustrating an example of a configuration of the sense amplifier units of the nonvolatile semiconductor memory device according to the present embodiment.

FIG. 4 illustrates an example in which a single sense amplifier unit SA is provided for a single bit line BL. The bit line BL and the sense amplifier unit SA are electrically connected to each other via a transistor HVTr. Each sense amplifier unit SA includes a single sense amplifier circuit SA′ and a plurality of data latch circuits LAT. The number of data latch circuits LAT that are provided are equal in number to the number of data bits which can be stored by each memory transistor MTr. For example, if each memory transistor MTr stores 2-bit data, and the number of the data latch circuits LAT is two as illustrated in FIG. 4. Each sense amplifier unit SA functions as a precharge circuit which precharges the bit line BL during a writing operation. The sense amplifier unit SA for the bit line BLb also functions as a current sense circuit which senses a current flowing through the bit line BLb during a reading operation. In addition, the sense amplifier circuit SA′ in the sense amplifier unit SAb is connected to the LAT in the sense amplifier unit SAa as illustrated in FIG. 4. The sense amplifier unit SAa may latch data read out from one of memory transistors MTrn-1a to MTr0a by the data latch circuit LATs in the sense amplifier unit SAa. On the other hand, the sense amplifier unit SAb may latch data read out from one of memory transistors MTrn-1b to MTr0b by the data latch circuit LATs in the sense amplifier unit SAb.

FIG. 5 illustrates an example in which a single sense amplifier unit SA is provided for two bit lines BLa and BLb via a bit line connection part BLI. The bit line BL and a cell source line CELSRC are electrically connected to each other via a high breakdown voltage transistor HVTr1 which is controlled by a control signal BIAS. The bit line BL and the bit line connection part BLI are electrically connected to each other via a high breakdown voltage transistor HVTr2 which is controlled by a control signal BLS. In addition, the bit line connection part BLI and the sense amplifier unit SA are electrically connected to each other via a low breakdown voltage transistor LVTr. The sense amplifier unit SA is obtained by combining the sense amplifier units SAa and SAb illustrated in FIG. 3. The sense amplifier unit SA includes a single sense amplifier circuit SA′ and a plurality of data latch circuits LAT. The data latch circuits LAT are necessary in a number obtained by multiplying a bit number of data which can be stored by each memory transistor MTr by the number of bit lines BL sharing the sense amplifier unit SA. For example, if each memory transistor MTr stores 2-bit data, two bit lines BL share a single sense amplifier unit SA, the number of data latch circuits LAT is four as illustrated in FIG. 5.

The sense amplifier unit SA illustrated in FIG. 5 functions as a precharge circuit which precharges the bit line BLa during a writing operation, and functions as a current sense circuit which detects a current flowing through the bit lines BLa and BLb during a reading operation.

In a case of the sense amplifier unit SA illustrated in FIG. 5, the high breakdown voltage transistors HVTr1 and HVTr2 are further provided as compared with the sense amplifier unit SA illustrated in FIG. 4. However, since the sense amplifier unit SA illustrated in FIG. 5 can be shared by two bit lines BL, one sense amplifier circuit SA′ formed by several tens of low breakdown voltage transistors LVTr and the like can be omitted. For this reason, the occupancy area can be reduced as compared with the configuration of the sense amplifier unit SA illustrated in FIG. 4.

However, in the sense amplifier unit SA illustrated in FIG. 5, data to be written is supplied to two bit lines BL, and thus there is a necessity of a sequence for supplying the data to be written in a time-division manner by using the control signal BLS during a writing operation.

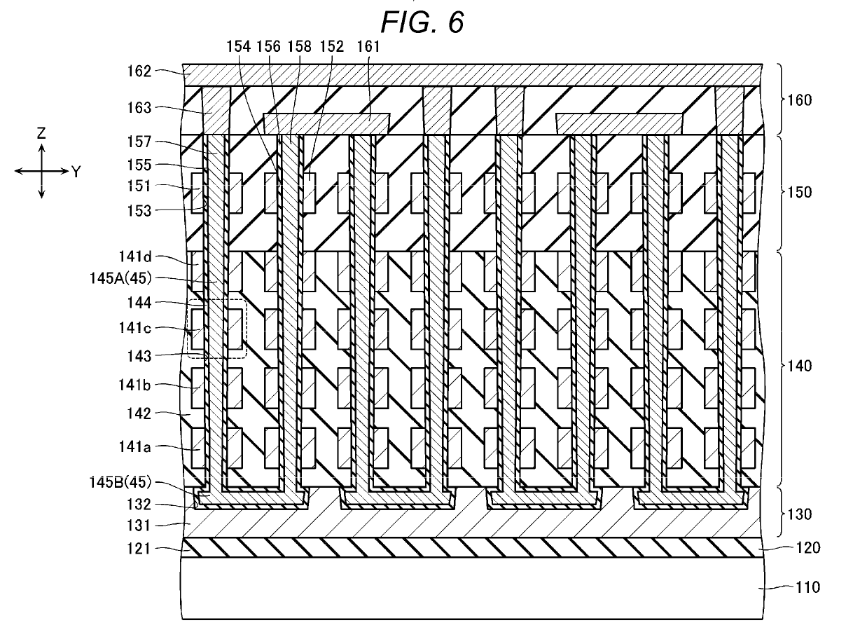

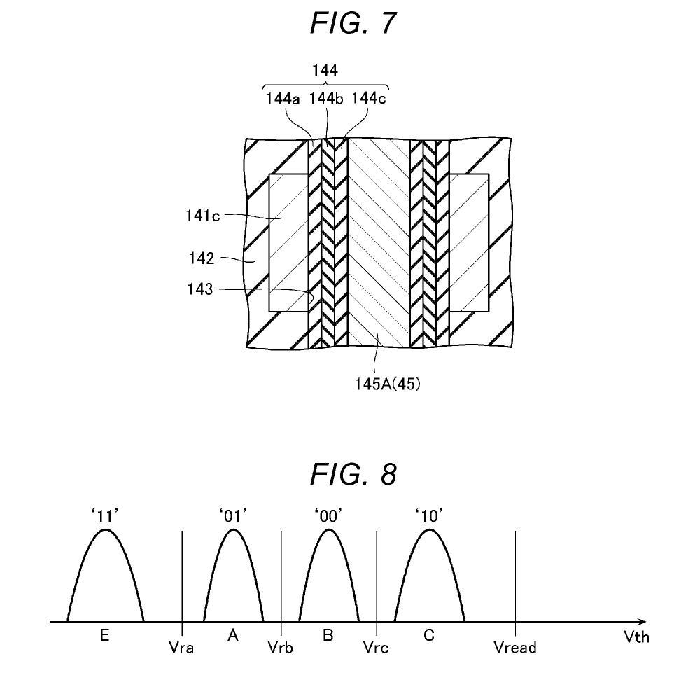

FIGS. 6 and 7 are cross-sectional views of the cell array in the nonvolatile semiconductor memory device according to the present embodiment. FIG. 6 is a cross-sectional view when the cell array 1 of FIG. 2 is viewed in the direction of A-A′. In addition, FIG. 7 is an enlarged cross-sectional view of a region indicated by the broken line of FIG. 6.

As illustrated in FIG. 6, the cell array 1 includes an insulating layer 120, a back gate layer 130 which functions as the back gate transistor BGTr, a memory transistor layer 140 which functions as the memory transistor MTr, a selection transistor layer 150 which functions as the source side selection transistor SSTr and the drain side selection transistor SDTr, and a wiring layer 160 which functions as the bit line BL, sequentially stacked on a semiconductor substrate 110.

The back gate layer 130 has a back gate conductive layer 131 which is formed on the semiconductor substrate 110 via the insulating layer 120. The back gate conductive layer 131 functions as the back gate line BG and a gate of the back gate transistor BGTr. In addition, the back gate layer 130 has a back gate groove 132 in which the back gate conductive layer 131 is formed.

The memory transistor layer 140 has a plurality of word line conductive layers 141 which are formed in the Z direction via insulating layers 142. The word line conductive layers 141 function as the word lines WL and gates of the memory transistors MTr. In addition, the memory transistor layer 140 has a memory hole 143 which is formed so as to penetrate through the plurality of word line conductive layers 141 and the plurality of insulating layers 142.

Further, the back gate layer 130 and the memory transistor layer 140 have a memory gate insulating layer 144 and a semiconductor layer 145. The memory gate insulating layer 144 is, as illustrated in FIG. 5, formed by a block insulating layer 144a, a charge storage layer 144b of the memory transistor MTr, and a tunnel insulating layer 144c, from the outside of the memory hole 143 to the inside thereof. The semiconductor layer 145 is formed in a U shape when viewed from the X direction, and has a connection part 145B which is formed so as to connect lower ends of a pair of pillar-shaped parts 145A vertically extending toward the semiconductor substrate 110 when viewed from the X direction. The semiconductor layer 145 functions as a body of the memory transistor MTr and the back gate transistor BGTr.

The selection transistor layer 150 has a drain side conductive layer 151 and a source side conductive layer 152 which are formed in the same layer. The drain side conductive layer 151 functions as the drain side selection gate line SGD and the gate of the drain side selection transistor SDTr. The source side conductive layer 152 functions as the source side selection gate line SGS and the gate of the source side selection transistor SSTr. In addition, the selection transistor layer 150 has a drain side hole 153, a source side hole 154, a drain side gate insulating layer 155, a source side gate insulating layer 156, a drain side pillar-shaped semiconductor layer 157, and a source side pillar-shaped semiconductor layer 158. The drain side pillar-shaped semiconductor layer 157 functions as a body of the drain side selection transistor SDTr. The source side pillar-shaped semiconductor layer 158 functions as a body of the source side selection transistor SSTr.

The wiring layer 160 has a first wiring layer 161, a second wiring layer 162, and a plug layer 163. The first wiring layer 161 functions as the bit line BLa. The second wiring layer 162 functions as the bit line BLb.

### Writing Operation and Reading Operation

Hereinafter, a writing operation and a reading operation for the memory transistor MTr will be described, and a relationship between the threshold voltage Vth and data of the memory transistor MTr will be described briefly.

FIG. 8 is a diagram illustrating a relationship between a threshold voltage and data of the memory transistor of the nonvolatile semiconductor memory device according to the present embodiment. FIG. 8 illustrates a case of the memory transistor MTr which stores four-value data.

Four voltage ranges, a level E, a level A, a level B, and a level C are set in order from a lower voltage in the threshold voltage Vth of the memory transistor MTr. The adjacent levels are differentiated from each other with a predetermined margin. In addition, for example, the level E, the level A, the level B, and the level C respectively correspond to four data values ‘11’, ‘01’, ‘00’ and ‘10’. The nonvolatile semiconductor memory device makes the threshold voltage Vth of the memory transistor MTr transition to a desired level so as to store four different data items.

Next, a writing operation according to the present embodiment will be described.

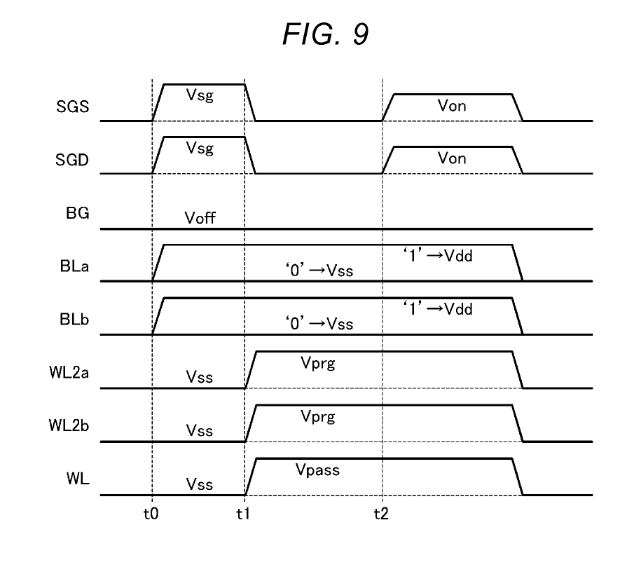

FIG. 9 is a timing chart during a writing operation in the nonvolatile semiconductor memory device according to the present embodiment. FIG. 9 illustrates a case where the memory transistor MTr2a (a first memory transistor) and the memory transistor MTr2b (a second memory transistor) are used as selection memory transistors which are writing targets. In the nonvolatile semiconductor memory device according to the present embodiment, the memory transistors MTr2a and MTr2b in the same layer are selected, and data is collectively written to the memory transistors MTr2a and MTr2b.

The writing operation is performed on a selected memory transistor MTr in an erasure state (a state of storing data ‘1’ in binary data and data ‘11’ in quaternary data) by the control circuit.

In the writing operation, when a data writing command is input from the controller 11 via the I/O, first, at the time point t0, the row decoder/word line driver 2a applies a voltage VSG for turning on a selected gate to the source side selection gate line SGS and the drain side selection gate line SGD such that the source side selection transistor SSTr and the drain side selection transistor SDTr are turned on, and applies an Off voltage Voff to the back gate line BG such that the back gate transistor BGTr is turned off. Accordingly, the pillar-shaped part CL1 and the pillar-shaped part CL2 are electrically disconnected from each other, and thus the pillar-shaped parts CL1 and CL2 are respectively electrically connected to the bit lines BLa and BLb.

In addition, in the present embodiment, the back gate transistor BGTr is used as a switch unit which electrically connects and disconnects the pillar-shaped part CL1 and the pillar-shaped part CL2 to and from each other, but any switch unit may be used as long as the switch unit can electrically connect and disconnect two selected memory transistors MTr to and from each other. For example, the memory transistors MTr0a, MTr1a, MTr0b and MTr1b between the selected memory transistors MTr2a and MTr2b may be used, or a new dummy transistor may be provided between the selected memory transistors MTr2a and MTr2b and may be used. However, as in the present embodiment, use of the back gate transistor BGTr as a switch unit is convenient since there is no necessity to install a new element.

At the time point t0, the sense amplifier unit SAa applies a voltage corresponding to data to be written to the selected memory transistor MTr2a of the pillar-shaped part CL1, to the bit line BLa which is electrically connected to the pillar-shaped part CL1 next. Similarly, the sense amplifier unit SAb applies a voltage corresponding to data to be written to the selected memory transistor MTr2b of the pillar-shaped part CL2, to the bit line BLb which is electrically connected to the pillar-shaped part CL2 next. At this time, the voltage applied to the bit line BL is an internal step-down power supply voltage Vdd, for example, if data to be written is ‘1’, and is a ground voltage Vss if data to be written is ‘0’.

Successively, at the time point t1, the row decoder/word line driver 2a applies a program voltage Vprg to the selected word lines WL2a and WL2b which are the gates of the selected memory transistors MTr2a and MTr2b. On the other hand, the row decoder/word line driver 2a applies an intermediate voltage Vpass to the unselected word line WL which is the gate of the unselected memory transistor MTr. Due to the application of the intermediate voltage Vpass, 0 V continues to be applied to the memory string MS to which data ‘0’ is written, but, in the memory string MS to which data ‘1’ is written, a channel inside the memory string MS is booted by capacitive coupling with the word line WL and thus a channel voltage increases. The selection transistors SDTr and SSTr are disconnected when the channel voltage increases, and thus the channel voltage increases up to the vicinity of the intermediate voltage Vpass (about 10 V), thereby realizing non-writing.

As a result, if a voltage of the bit line BLa is the ground voltage Vss, electrons are injected into the charge storage layer of the selected memory transistor MTr2a, and thus the threshold voltage Vth increases such that data ‘0’ is written. On the other hand, if a voltage of the bit line BLa is the internal step-down power supply voltage Vdd, electrons are not injected into the charge storage layer of the selected memory transistor MTr2a, and thus the threshold voltage Vth is maintained such that data remains ‘1’. The selected memory transistor MTr2b of the pillar-shaped part CL2 is the same as in a case of the selected memory transistor MTr2a of the pillar-shaped part CL1, and thus description thereof will be omitted.

As described above, the writing operation for the memory transistor MTr is completed.

Here, effects of the present embodiment will be described using the following comparative example.

FIG. 18 is a circuit diagram of a memory string of a cell array in a nonvolatile semiconductor memory device according to a comparative example of the first embodiment.

As illustrated in FIG. 18, the memory string MS according to the comparative example is different from the memory string MS according to the present embodiment in that one end of the source side selection transistor SSTr is connected to a source line SL. The source line SL is not connected to the sense amplifier unit SAa. In addition, assigning addresses to the word line WL and the memory transistor MTr is also different. Specifically, in the comparative example, addresses 0 to n−1 and n to 2n−1 are respectively assigned to the memory transistors MTrn-1a to MTr0a and MTr0b to MTrn-1b of the present embodiment. Further, in the comparative example, addresses 0 to n−1 and n to 2n−1 are respectively assigned to the word lines WLn-1a to WL0a and WL0b to WLn-1b of the present embodiment.

In addition, a writing operation according to the comparative example is as follows.

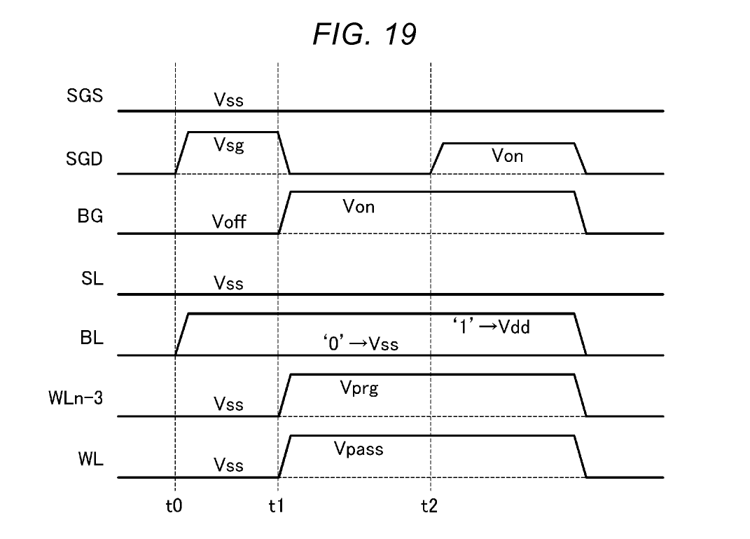

FIG. 19 is a timing chart during a writing operation in the nonvolatile semiconductor memory device according to the comparative example. FIG. 19 illustrates a case where the memory transistor MTrn−3 (corresponding to the memory transistor MTr2a of the present embodiment) is used as a selected memory transistor.

When a data writing command is input from the controller via the I/O, first, at the time point t0, the row decoder/word line driver turns off the source side selection transistor SSTr, and applies a voltage Vsg for turning on the selection transistor SDTr to the drain side selection transistor SDTr.

Successively, at the time point t0, the sense amplifier unit SA (a device corresponding to the sense amplifier unit SAb of the present embodiment) applies the internal step-down power supply voltage Vdd or the ground potential Vss to the bit line BL (corresponding to the bit line BLb of the present embodiment) according to data. At this time, the back gate transistor BGTr is in a turned-on state.

Subsequently, at the time point t1, the row decoder/word line driver applies the program voltage Vprg to only a single selected word line WLn−3 (corresponding to the word line WL2a of the present embodiment) and applies the intermediate voltage Vpass to the other unselected word lines WL. Due to the application of the intermediate voltage Vpass, 0 V continues to be applied to the memory string to which data ‘0’ is written, but, in the memory string to which data ‘1’ is written, a channel inside the memory string MS is booted by capacitive coupling with the word line WL and thus a channel voltage increases. The selection transistors SDTr and SSTr are disconnected when the channel voltage increases, and thus the channel voltage increases up to the vicinity of the intermediate voltage Vpass (about 10 V), thereby realizing non-writing.

As a result, electrons are injected into the charge storage layer of the selected memory transistor MTrn−3 according to a voltage of the bit line BL, and thus the threshold voltage Vth of the selected memory transistor MTrn−3 transitions. Accordingly, the writing operation for the selected memory transistor MTrn−3 is completed.

In the writing operation of the comparative example, the row decoder/word line driver applies the program voltage Vprg to the selected word line WLn−3 and also applies the intermediate voltage Vpass to the unselected word line WLn+2 adjacent to the selected word line WLn−3 in the Y direction. For this reason, a great voltage difference occurs between the word line WLn−3 and the word line WLn+2. As a result, a parasitic capacitance of the memory string MS increases, and a throughput of the writing operation is reduced by the increase amount.

In the present embodiment, the program voltage Vprg is simultaneously applied, as a selected word line, to two word lines WL2a and WL2b which are located at the same position in the Z direction and are adjacent to each other in the Y direction, and thus a voltage difference does not occur between the word lines WL2a and WL2b. For this reason, a parasitic capacitance of the memory string MS can be reduced as compared with the comparative example. In addition, the writing operation is simultaneously performed on two memory transistors MTr, and thus a throughput and reliability of the writing operation can be improved as compared with the comparative example.

Next, a reading operation according to the present embodiment will be described.

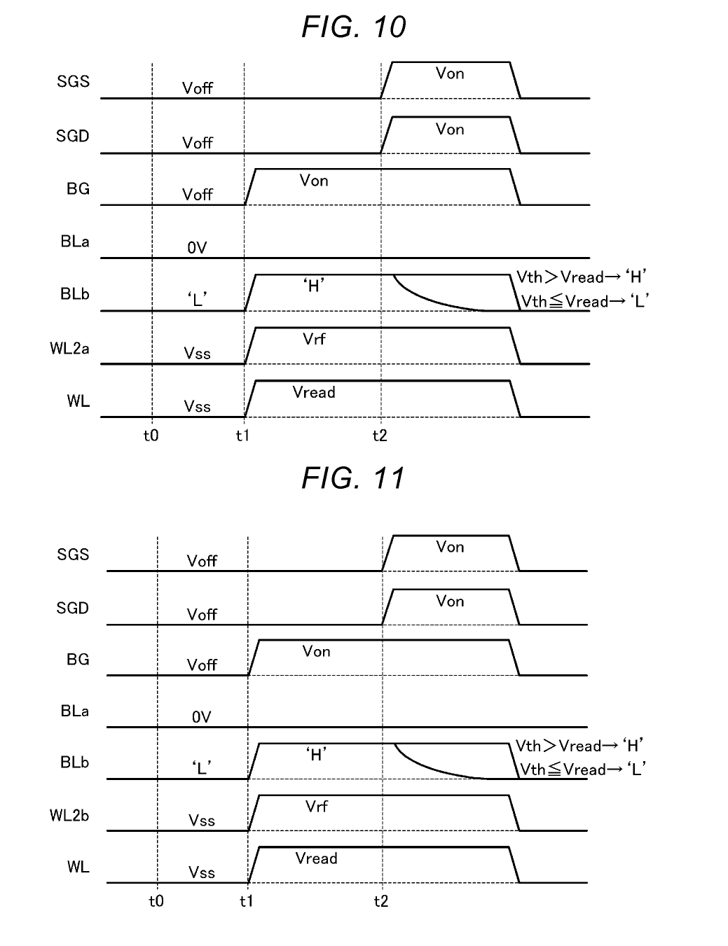

FIGS. 10 and 11 are timing charts during a reading operation in the nonvolatile semiconductor memory device according to the present embodiment. FIG. 10 illustrates a case where the memory transistor MTr2a of the pillar-shaped part CL1 is used as a selected memory transistor, and FIG. 11 illustrates a case where the memory transistor MTr2b of the pillar-shaped part CL2 is used as a selected memory transistor.

The reading operation is performed by the control circuit.

In the reading operation for the memory transistor MTr2a of the pillar-shaped part CL1, when a data reading command is input from the controller 11 via the I/O, first, at the time point t0, the row decoder/word line driver 2a applies an Off voltage to the source side selection gate line SGS and the drain side selection gate line SGD so as to turn off the source side selection transistor SSTr and the drain side selection transistor SDTr.

Successively, at the time point t1, the row decoder/word line driver 2a applies an On voltage Von to the back gate line BG so as to turn on the back gate transistor BGTr in a state of maintaining the source side selection transistor SSTr and the drain side selection transistor SDTr in an Off state. In addition, the sense amplifier unit SAb charges the bit line BLb to an ‘H’ level, and initializes a sense level. Further, the sense amplifier unit SAa applies 0 V to the bit line BLa.

Furthermore, the row decoder/word line driver 2a applies a reference voltage Vrf to the selected word line WL2a, and applies a reading voltage Vread to the unselected word line WL. Here, the reference voltage Vrf is any one of, for example, a voltage Vra between the level E and the level A, a voltage Vrb between the level A and the level B, and a voltage Vrc between the level B and the level C, illustrated in FIG. 8. In addition, the reading voltage Vread is a voltage higher than the highest level C. For this reason, the unselected memory transistors MTr are all turned on regardless of data stored therein.

Finally, at the time point t2, the row decoder/word line driver 2a applies the On voltage Von to the source side selection gate line SGS and the drain side selection gate line SGD so as to turn on the source side selection transistor SSTr and the drain side selection transistor SDTr. As a result, if the threshold voltage Vth of the selected memory transistor MTr2a is lower than the reference voltage Vrf of the selected word line WL2a, the memory string MS conducts such that a current flows toward the bit line BLa from the bit line BLb, and thus a sense level of the bit line BL is reduced to an ‘L’ level. On the other hand, if the threshold voltage Vth of the selected memory transistor MTr2a is higher than the reference voltage Vrf of the selected word line WL2a, a current does not flow from the bit line BL, and thus a sense level of the bit line BL is maintained in an ‘H’ level. In addition, the sense amplifier unit SAb detects the current flowing through the bit line BL, and thus data of the selected memory transistor MTr2a can be discriminated.

A reading operation for the memory transistor MTr2b of the pillar-shaped part CL2 is the same as the reading operation for the memory transistor MTr2a of the pillar-shaped part CL1 except that the reference voltage Vrf is applied to the selected word line WL2b, and the reading voltage Vread is applied to the unselected word line WL2a, and thus description thereof will be omitted.

The reading operation according to the present embodiment is performed after the back gate transistor BGTr is turned on and the pillar-shaped parts CL1 and CL2 are electrically connected to each other unlike the writing operation. Accordingly, a reading operation for a single memory transistor MTr for each memory string MS can be realized in the same manner as in the related art, by using the circuit configuration for performing the above-described writing operation. In addition, even if a selected memory transistor belongs to either of the pillar-shaped parts CL1 and CL2, a current flowing through the bit line BLb is detected, and thus the sense amplifier unit SAa on the bit line BLa side is not required to have a current sense circuit. For this reason, a configuration of the sense amplifier unit SAa can be simplified, and thus an increase in the occupancy area of the sense amplifier unit SAa formed on the semiconductor substrate can be suppressed.

In a case of a memory string with a BiCS structure having a U-shaped memory string, a single word line has word lines adjacent thereto horizontally and vertically. In addition, word lines having separate addresses may be adjacent to each other. For this reason, a capacitance between adjacent word lines increases depending on a bias state during a writing operation, and this causes deterioration in reliability or in throughput of the writing operation.

In the present embodiment, a writing operation is simultaneously performed on word lines adjacent in the Y direction as a selected word line, and thus a parasitic capacitance occurring between the adjacent word lines can be reduced. In addition, in the present embodiment, the writing operation is simultaneously performed on two memory transistors for each memory string. Therefore, according to the present embodiment, reliability and throughput of the writing operation can be improved. Further, although more sense amplifier units are required to be prepared than in the comparative example, as described above, in the reading operation, only a current of one bit line is required to be detected, and thus a configuration of the sense amplifier unit on the other bit line side can be simplified. Therefore, an increase in the occupancy area of the sense amplifier unit can be suppressed.

### Second Embodiment

The second embodiment is an application example of the first embodiment, and is a modification example of the switch unit of the memory string MS. Here, differences from the first embodiment will be mainly described.

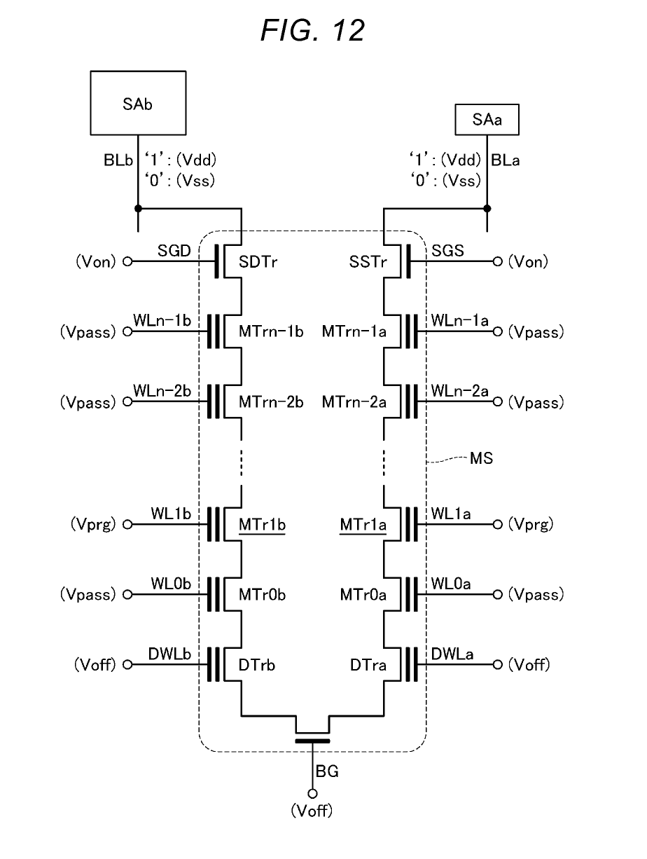

FIG. 12 is a circuit diagram of a memory string of a cell array in a nonvolatile semiconductor memory device according to the present embodiment.

In the memory string MS according to the present embodiment, unlike in the first embodiment, dummy transistors DTra and DTrb, which respectively have dummy word lines DWLa and DWLb as gates, are inserted between the memory transistors MTra and MTrb and the back gate transistor BGTr around the back gate transistor BGTr. The dummy word line DWL has the same structure as the structure of the word line WL. In addition, the dummy transistor DTr has the same structure as the structure of the memory transistor MTr and thus can store data, but is not treated as a memory element. In the present embodiment, a switch unit is formed using the dummy transistor DTr in addition to the back gate transistor BGTr.

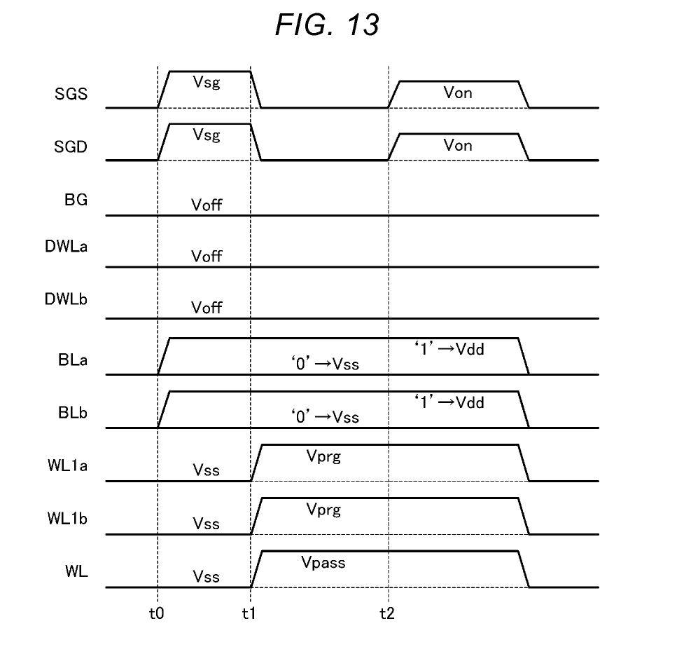

FIG. 13 is a timing chart during a writing operation in the nonvolatile semiconductor memory device according to the present embodiment.

In the writing operation according to the present embodiment, unlike in the first embodiment, the pillar-shaped part CL1 and the pillar-shaped part CL2 are electrically disconnected from each other using the dummy transistors DTra and DTrb as well as the back gate transistor BGTr. Specifically, during the writing operation, the row decoder/word line driver 2a applies a low voltage (for example, the Off voltage Voff illustrated in FIG. 13) between the intermediate voltage Vpass and the ground voltage Vss to the dummy word lines DWLa and DWLb so that the dummy transistors DTra and DTrb are turned to a cutoff state.

In this way, according to the present embodiment, the same effects as in the first embodiment can be achieved, and the pillar-shaped parts CL1 and CL2 can be more reliably electrically disconnected from each other than in the first embodiment.

### Third Embodiment

The third embodiment is an application example of the first embodiment, and is a modification example of the structure of the cell array 1. Here, differences from the first embodiment will be mainly described.

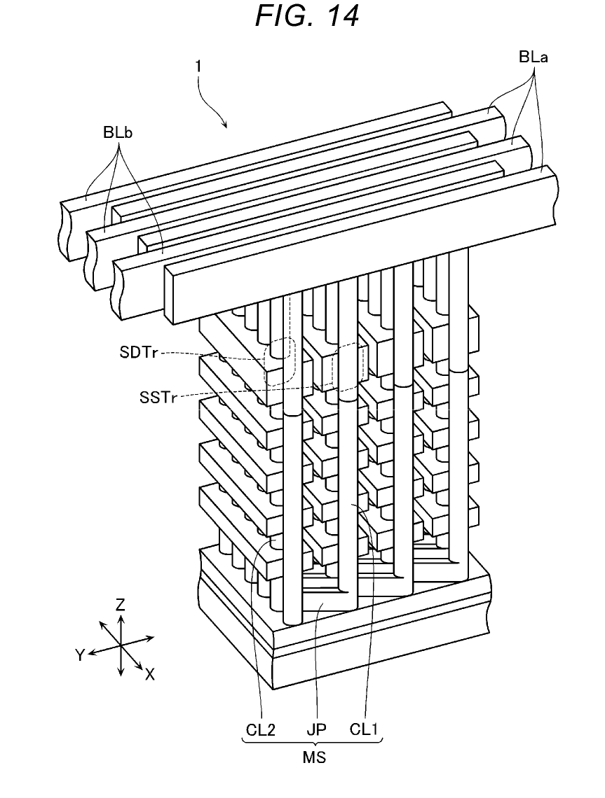

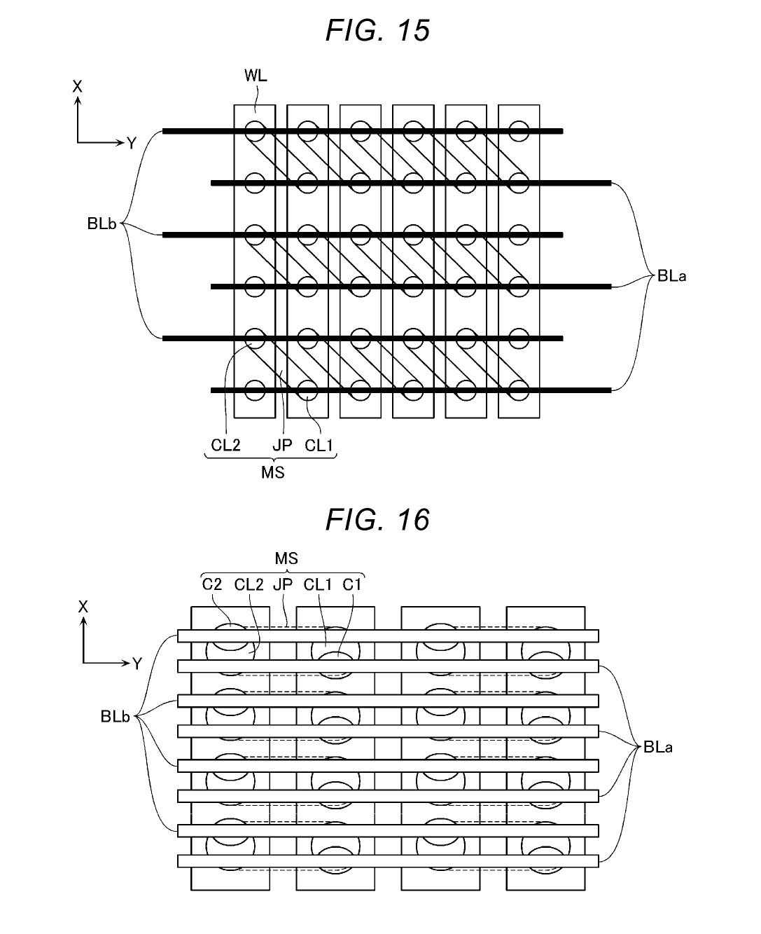

FIG. 14 is a perspective view illustrating a structure of a cell array of a nonvolatile semiconductor memory device according to the present embodiment. In addition, FIG. 15 is a plan view when the same cell array is viewed from the Z direction.

In the same manner as in the first embodiment, a pillar of a memory string MS of the cell array 1 illustrated in FIG. 14 has a U shape, and includes a pillar-shaped part CL1 which is connected to the bit line BLa via the source side selection transistor SSTr, a pillar-shaped part CL2 which is connected to the bit line BLb via the drain side selection transistor SDTr, and a connection part JP which connects lower ends of the pillar-shaped parts CL1 and CL2 to each other. However, in the first embodiment, the pillar-shaped part CL1 of the pillar is located at the same position as the pillar-shaped part CL2 in the X direction and is adjacent thereto in the Y direction, but, in the third embodiment, the pillar-shaped part CL1 is deviated from the pillar-shaped part CL2 at positions thereof in the X direction. In addition, in the present embodiment, the pillar-shaped part CL1 is disposed between a plurality of bit lines BLb when viewed from the Z direction as illustrated in FIG. 14. As a result, in the present embodiment, the bit line BLa can be formed in the same layer as the bit line BLb unlike in the first embodiment.

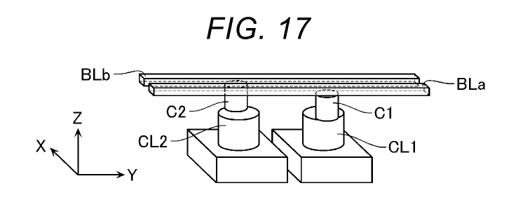

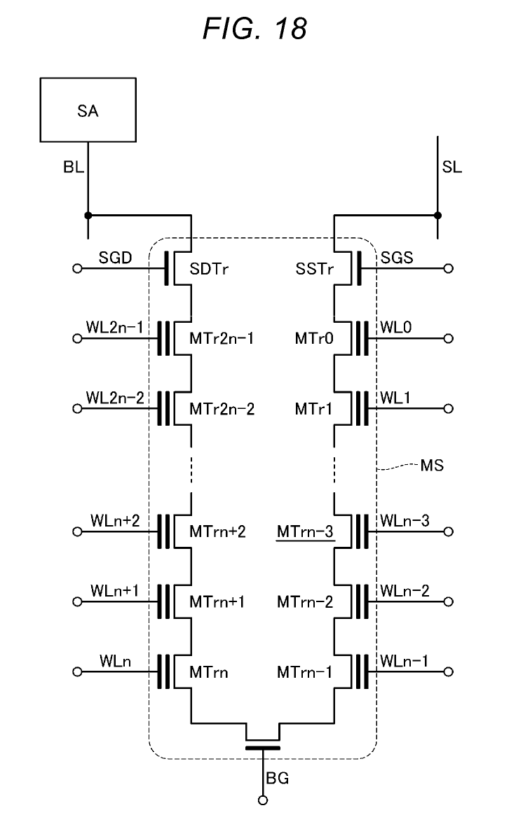

FIG. 16 is a plan view when another cell array of the nonvolatile semiconductor memory device according to the present embodiment is viewed from the Z direction. In addition, FIG. 17 is a perspective view illustrating a structure of the same cell array.

A pillar of the memory string MS of the cell array 1 illustrated in FIG. 16 is formed using two pillar-shaped parts CL1 and CL2 which are disposed at the same position in the X direction and are adjacent to each other in the Y direction unlike in the case of FIG. 14. Here, the memory string MS has a direct contact C1 which connects the pillar-shaped part CL1 to the bit line BLa and a direct contact C2 which connects the pillar-shaped part CL2 to the bit line BLb as illustrated in FIG. 17. In addition, these direct contacts C1 and C2 are disposed at different positions in the X direction. For this reason, the bit lines BLa and BLb can be formed in the same layer even if the connection part JP is not formed obliquely as illustrated in FIG. 14.

As described above, according to the present embodiment, the same effects as in the first embodiment can be achieved, and a manufacturing cost can be reduced due to a reduction of the number of wiring layers as compared with the first embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile semiconductor memory device comprising:
a memory string that includes a plurality of first memory cells, a plurality of second memory cells, and a transistor electrically connected between the plurality of first memory cells and the plurality of second memory cells; and
a control circuit configured to perform a program operation by applying a program voltage to a gate of a selected first memory cell among the plurality of first memory cells and a gate of a selected second memory cell among the plurality of second memory cells, a pass voltage lower than the program voltage to other memory cells in the plurality of first and second memory cells, and a first control voltage lower than the pass voltage to a gate of the transistor.

2. The device according to claim 1, wherein the first memory cells and the second memory cells are stacked above a substrate and the selected first memory cell and the selected second memory cell are at substantially the same height along a stacking direction.

3. The device according to claim 1, wherein
the control circuit is configured to perform a data reading operation by applying a second control voltage to the gate of the transistor, the second control voltage being higher than the first control voltage.

4. The device according to claim 1, wherein
the memory string further includes at least one dummy cell between the first memory cells and the transistor and at least one dummy cell between the second memory cells and the transistor, and
the control circuit is configured to turn off the dummy cells during the program operation.

5. The device according to claim 1, further comprising first and second bit lines, the first memory cells being electrically connected between the first bit line and the transistor and the second memory cells being electrically connected between the second bit line and the transistor.

6. The device according to claim 5, wherein the first bit line extends in a first direction and the second bit line extends in a second direction that is orthogonal to the first direction.

7. The device according to claim 5, wherein the first bit line extends in a first direction and the second bit line extends in a second direction that is parallel to the first direction.

8. A nonvolatile semiconductor memory device comprising:
a memory string that includes a plurality of first memory cells, a plurality of second memory cells, and a transistor electrically connected between the plurality of first memory cells and the plurality of second memory cells; and
a control circuit including a first control unit for the first memory cells and a second control unit for the second memory cells, the first control unit including a precharge circuit, a sense circuit, and a latch circuit, the second control unit including a precharge circuit and a latch circuit.

9. The device according to claim 8, wherein the second control circuit does not include a sense circuit.

10. The device according to claim 8, wherein
the control circuit is configured to perform a program operation by applying a first control voltage to the gate of the transistor.

11. The device according to claim 8, wherein
the control circuit is configured to perform a data reading operation by applying a second control voltage to the gate of the transistor, the second control voltage being higher than the first control voltage.

12. The device according to claim 8, wherein
the memory string further includes at least one dummy cell between the first memory cells and the transistor and at least one dummy cell between the second memory cells and the transistor, and
the control circuit is configured to turn off the dummy cells during a program operation and turn on the dummy cells during a data reading operation.

13. The device according to claim 8, further comprising first and second bit lines, the first memory cells being electrically connected between the first bit line and the transistor and the second memory cells being electrically connected between the second bit line and the transistor.

14. The device according to claim 8, wherein the first bit line extends in a first direction and the second bit line extends in a second direction that is orthogonal to the first direction.

15. The device according to claim 14, wherein the first bit line extends in a first direction and the second bit line extends in a second direction that is parallel to the first direction.

16. A method of controlling a nonvolatile semiconductor memory device having a memory string that includes a plurality of first memory cells, a plurality of second memory cells, and a transistor electrically connected between the plurality of first memory cells and the plurality of second memory cells, said method comprising:
during a program operation, applying a program voltage to a gate of a selected first memory cell among the plurality of first memory cells and a gate of a selected second memory cell among the plurality of second memory cells, a pass voltage lower than the program voltage to other memory cells in the plurality of first and second memory cells, and a first control voltage to a gate of the transistor.

17. The method of claim 16, wherein the first memory cells and the second memory cells are stacked above a substrate and the selected first memory cell and the selected second memory cell are at substantially the same height along a stacking direction.

18. The method of claim 16, further comprising:
during a data reading operation, applying a second control voltage to the gate of the transistor, the second control voltage being higher than the first control voltage.

19. The method of claim 18, wherein the nonvolatile semiconductor memory device includes a first sense amplifier unit for the first memory cells and a second sense amplifier unit for the second memory cells, and a current sense circuit provided in the first sense amplifier is used to sense a current flowing through the first memory cells, the transistor, and the second memory cells during the data reading operation.

20. The method of claim 16, wherein the memory string further includes at least one dummy cell between the first memory cells and the transistor and at least one dummy cell between the second memory cells and the transistor, and the dummy cells are turned off during the program operation.
